(19) United States
(12) Patent Application Publication
(10) Pub. No.: US 2004/0140475 A1
(43) Pub. Date: Jul. 22, 2004

(54) 3D MEMS/MOEMS package

(75) Inventors: Yi-Sheng Sun, San Jose, CA (US); Desmond Chong Yok Rue, Singapore (SG); Rahul Kapoor, Singapore (SG)

Correspondence Address: GREENBLUM & BERNSTEIN, P.L.C., 1950 ROLAND CLARKE PLACE, RESTON, VA, 20191, US

(73) Assignee: United Test & Assembly Center Limited, Singapore (SG)

(21) Appl. No.: 10/347,406

(22) Filed: Jan. 21, 2003

(51) Int. Cl. H01L 33/00

(52) U.S. Cl. 257/100

(57) ABSTRACT

Two substrates each carrying MEMS or MOEMS structures are bonded face to face and interconnected to form a compact surface-mountable package.

The present invention relates to packaged micro-electro-mechanical-systems (MEMS) or micro-optical-electromechanical systems (MOEMS) and to methods of packaging such systems.

In known MEMS devices, structures are disposed on a single surface of a single substrate. Multiple structures must be placed side by side to form more complex devices so that increasing complexity results in increasing area. This does not result in efficient board utilization efficiency and limits the extent to which products can be made smaller.

It is an aim of the present invention to provide a compact package structure for multiple MEMS and MOEMS devices as well as a method of packaging such devices.

According to the present invention there is provided a packaged MEMS or MOEMS device comprising a first substrate having on a first surface thereof at least one MEMS or MOEMS structure and a second substrate opposing and spaced from said first surface of said first substrate, said second substrate having at least one MEMS or MOEMS structure on a first surface thereof and being bonded to the first surface of said first substrate.

By stacking two substrates with MEMS or MOEMS devices on them, a more complex device can be created with no increase in surface scale. At the same time, a surface-mountable package, allowing testing in wafer form (in-process testing), can be made. The package of the invention can be mounted onto a printed circuit board or the like using standard surface mount technology. Existing processes and equipment can be used, avoiding the need for capital investment in obtaining new equipment and developing new mounting processes. Furthermore, the package can be tested in wafer form, which also reduces costs. It is also easy to combine MEMS or MOEMS devices of different types in a single package.

Preferably, the first and second substrates are bonded by a ring of polymeric material which provides a strong and secure bond.

In preferred embodiments of the present invention, interconnections between the first and second substrates are provided. These may provide electrical connections between devices on the same or different substrates. An outer ring of interconnections may also provide an hermetic seal to prevent outgassing into the MEMS/MOEMS environment. The interconnections may be formed by electroplated gold studs, by electroless plated nickel/gold studs or by solder bumps.

The first substrate may be of an organic type and the second substrate may be made of glass or silicon.

An exemplary embodiment of the present invention will be described below with reference to the accompanying schematic drawings in which:

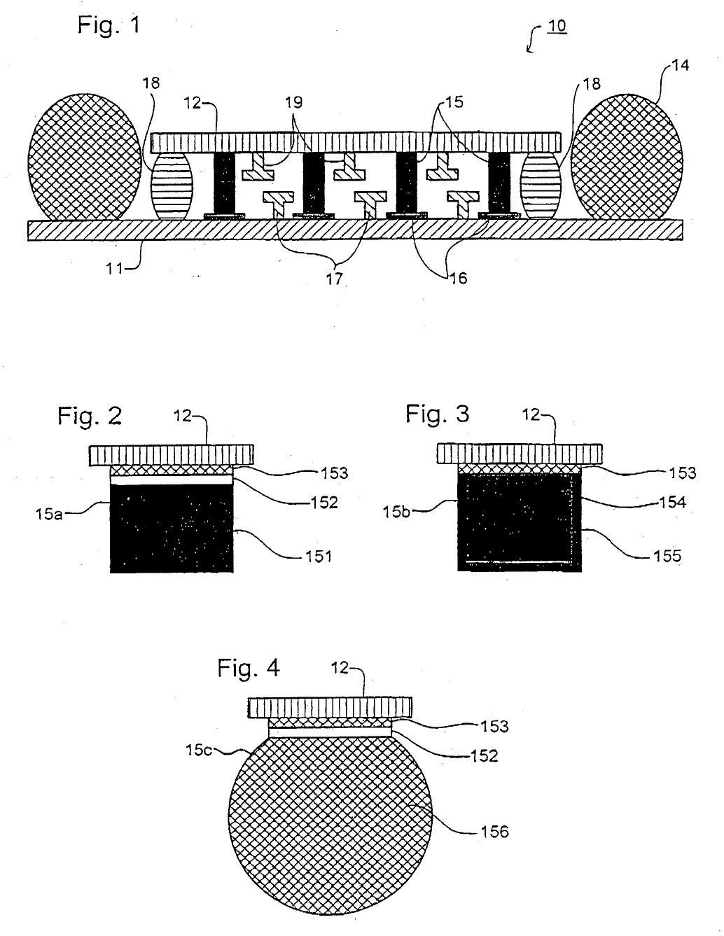

FIG. 1 is a cross-sectional view of a packaged device according to the present invention;

FIG. 2 is a cross-section of an electroplated gold stud usable to form interconnections in embodiments of the present invention;

FIG. 3 is a cross-section of an electroless plated nickel/gold stud usable in embodiments of the present invention;

FIG. 4 is a cross-sectional view of a solder bump usable to provide interconnections in an embodiment of the present invention; and

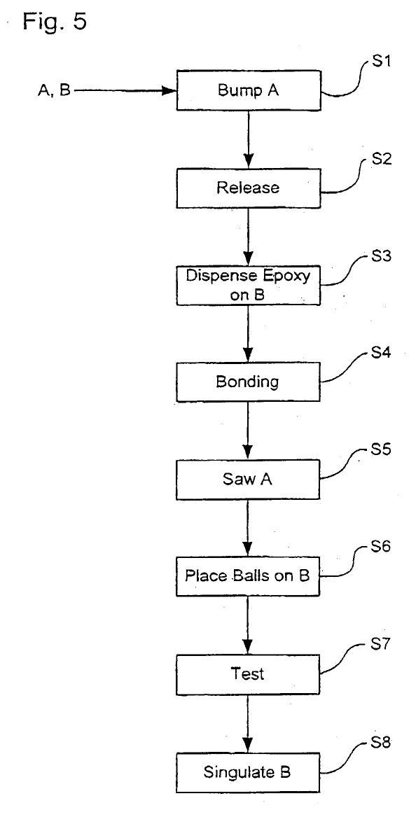

FIG. 5 is a flow diagram of a process for manufacturing devices according to an embodiment of the present invention.

In the various drawings, like references indicate like parts.

A preferred embodiment of the present invention is shown in cross-section in FIG. 1. The packaged device 10 comprises a first substrate 11 which has on a first surface thereof and MEMS or MOEMS structures 17. Spaced from and facing the first surface of the first substrate 11 is a second substrate 12. Second substrate 12, also carries MEMS or MOEMS structures on its lower surface, facing the first surface of first substrate 11 which carries MEMS or MOEMS structures. The structures on the two wafers may be the same or different. The separation between the first and second substrates may be in the range of 1 to 20 μm. The first and second substrates are bonded together by a ring of polymeric material 18, e.g. epoxy resin, and by interconnections or joints 15 provided on metal pads 16. The interconnections or joints 15 may serve two functions. An outer ring of the joints provides an hermetic seal to prevent outgassing into the MEMS/MOEMS environment. Inner ones of the joints provide interconnections for the MEMS or MOEMS devices on the two substrates.

The second substrate may cover all MEMS or MOEMS structures on the first substrate or may leave some structures uncovered to allow mechanical or optical access.

Both substrates 11, 12 may be silicon or glass wafers. The latter type is particularly appropriate if optical access to the MOEMS structures is required.

The second substrate 12 has a smaller area than the first substrate 11 so that solder balls 14 may be provided on the outer periphery of first substrate 11 allowing connections to external terminals via known surface mounting techniques.

Three possible forms of the joints 15 can be used; electroplated gold studs, electroless plated nickel/gold studs and bumps. An electroplated gold stud 15a is shown in FIG. 2. Over the I/O pad 153 a layer of under-bump metallization is provided on top of which is the gold stud 151. FIG. 3 shows an electroless plated nickel/gold stud 15b which comprises a nickel core 154 of 5 to 20 μm thickness provided on the I/O pad 153. A gold plating 155 of thickness about 0.05 to 0.5 μm coats the nickel core 154. A solder bump is shown in FIG. 4; in this structure a ball 156 of solder, e.g. comprising a combination of one or more of Sn, Pb, Ag, Cu, In, bismuth, is provided on a layer of UBM 152 which overlies I/Q pad 153.

A process for the manufacture of a package according to the present invention is shown in FIG. 5. Two wafers A and B are provided. Wafer A is to form the second substrate of the finished package and wafer B is to form the first substrate of the completed package. Both substrates carry a plurality of MEMS or MOEMS devices. Wafer A is provided with electroplated gold studs, electroless nickel/gold plated studs or high temperature solder bumps in step S1 to form the interconnections or joints in the finished package. This wafer is then released in step 52 and in step S3 epoxy is dispensed onto substrate B, which carries the MEMS or MOEMS structure, for bonding the two wafers together. The bonding is carried out at step S4. In step S5 wafer A is sawn to allow placement of solder balls which are used for interconnections to external terminals in the finished package in step 56. In step S7 the devices are tested before being singulated in step S8.

Whilst we have described above a preferred embodiment of the present invention it is to be appreciated that the present invention can be embodied in other forms and that modification to the described embodiments will occur to the skilled person. Accordingly, the scope of the present invention is defined by the appended claims rather than by the foregoing description.

1. A packaged MEMS or MOEMS device comprising:
a first substrate having on a first surface thereof at least one MEMS or MOEMS structure; and
a second substrate opposing and spaced from said first surface of said first substrate, having at least one MEMS or MOEMS structure on a first surface thereof opposing said first surface of said first substrate and said second substrate being bonded to said first surface of said first substrate.

2. A device according to claim 1 wherein said first substrate has on its first surface contacts for surface mounting of the device.

3. A device according to claim 1 or 2 further comprising a plurality of joints between said first and second substrates to make electrical interconnections between structures on said first substrate.

4. A device according to claim 1, 2 or 3 further comprising an hermetic seal between said first and second substrates enclosing said MEMS or MOEMS structure.

5. A device according to claim 1, 2, 3 or 4 wherein said first and second substrates are bonded together by a polymeric material.

6. A device according to any one of the preceding claims wherein said first substrate is made of an organic material.

7. A device according to any one of the preceding claims wherein said second substrate is formed by silicon or glass.

8. A device according to any one of the preceding claims wherein the separation between said first and second substrates is in the range of from 1 to 20 μm.

9. A method of packaging a plurality of MEMS or MOEMS device provided on respective first surfaces of a first and a second substrate, the method comprising the step of:
bonding said second substrate to said first substrate in a spaced apart relationship so that said respective first surfaces oppose each other.

10. A method according to claim 9 further comprising the step of providing electrical contacts for electrical connection to terminals to enable surface mounting of said packaged device.

11. A method according to claim 9 or 10 wherein said step of bonding comprises forming a ring of epoxy resin around said MEMS or MOEMS device.

12. A method according to claim 9, 10 or 11 further comprising the step of forming electrical interconnections between device formed on said first substrate via said second substrate.

13. A method according to any one of claims 9 to 12 further comprising the step of forming an hermetic seal between said first and second substrate around said MEMS or MOEMS devices.

14. A method according to any one of claims 9 to 13 wherein a plurality of MEMS or MOEMS devices are provided on each of said first and second substrates and said devices are singulated after bonding of said second substrate to said first substrate.
